(19) United States
(12) Patent Application Publication
(10) Pub. No.: US 2016/0093758 A1
(43) Pub. Date: Mar. 31, 2016

(54) SOLAR CELL

(71) Applicant: Panasonic Intellectual Property Management Co., Ltd., Osaka (JP)

(72) Inventor: Daisuke FUJISHIMA, Osaka (JP)

(21) Appl. No.: 14/864,443

(22) Filed: Sep. 24, 2015

(30) Foreign Application Priority Data
Sep. 25, 2014 (JP) 2014-195579

(51) Int. Cl. H01L 31/05

(52) U.S. Cl. CPC H01L 31/0516

(57) ABSTRACT

A solar cell includes a photoelectric conversion unit, where a first conductive-type layer and a second conductive-type layer are arranged alternately on a main surface of the semiconductor substrate, and an electrode layer provided on the first conductive-type layer and the second conductive-type layer. The photoelectric conversion unit has a plurality of sub-cells. The electrode layer has a first electrode, provided on the first conductive-type layer included in a sub-cell at one end of the sub-cells, a second electrode, provided on the second conductive-type layer included in a sub-cell at the other end of the sub-cells, and a sub-electrode provided across two adjacent sub-cells. A sub-cell, where the first electrode is provided, has a larger area of the main surface than that of a sub-cell where the second electrode is provided.

### RELATED APPLICATION

Priority is claimed to Japanese Patent Application No. 2014-195579, filed on Sep. 25, 2014, the entire content of which is incorporated herein by reference.

### BACKGROUND OF THE INVENTION

1. Field of the Invention

The present invention relates to a solar cell and more particularly to a back-contact type solar cell.

2. Description of the Related Art

As a solar cell having a high power generation efficient, there is available a back-contact type solar cell. In this back-contact solar cell, both an n-type region and a p-type region are formed on a back surface disposed counter to a light-receiving surface on which light is incident. In the back-contact solar cell, both an n-side electrode and a p-side electrode by which the electric power generated is to be extracted are provided on the back surface of the solar cell. The n-side electrode and the p-side electrode are each formed in a comb teeth shape.

### SUMMARY OF THE INVENTION

It is beneficial that a back-contact solar cell be so configured as to enhance a current collecting efficiency.

The present invention has been made in view of the foregoing circumstances, and a purpose thereof is to provide a solar cell having an increased power generation efficiency.

In order to resolve the above-described problems, a solar cell according to one embodiment of the present invention includes: a photoelectric conversion unit including: a semiconductor substrate having one conductivity type; a first conductive-type layer provided on a main surface of the semiconductor substrate, the first conductive-type layer having the same conductivity type as that of the semiconductor substrate; and a second conductive-type layer provided on the main surface, the second conductive-type layer having a conductivity type different from that of the semiconductor substrate, wherein the first conductive-type layer and the second conductive-type layer are arranged alternately in a first direction on the main surface, and an electrode layer provided on the first conductive-type layer and the second conductive-type layer. The photoelectric conversion unit has a plurality of sub-cells, arranged in a second direction that intersects with the first direction, and a separation region provided on a boundary between adjacent sub-cells. The electrode layer has: a first electrode provided on the first conductive-type layer included in a sub-cell at one end of the plurality of sub-cells; a second electrode provided on the second conductive-type layer included in a sub-cell at the other end of the plurality of sub-cells; and a sub-electrode provided across two adjacent sub-cells, the sub-electrode connecting the first conductive-type layer included in one of the two adjacent sub-cells and the second conductive-type layer included in the other thereof. A sub-cell, where the first electrode is provided, has a larger area of the main surface than that of a sub-cell where the second electrode is provided.

### BRIEF DESCRIPTION OF THE DRAWINGS

Embodiments will now be described by way of examples only, with reference to the accompanying drawings which are meant to be exemplary, not limiting, and wherein like elements are numbered alike in several Figures in which:

FIG. 1 is a plane view showing a solar cell according to a first embodiment;

FIG. 2 is a plane view of a solar cell according to a first embodiment;

FIG. 3 is a cross-sectional view showing a structure of a solar cell according to a first embodiment;

FIG. 4 is a cross-sectional view showing a structure of a first conductive-type region of a solar cell according to a first embodiment;

FIG. 5 is a cross-sectional view showing a structure of a second conductive-type region of a solar cell according to a first embodiment;

FIG. 6 is a plane view showing a structure of a sub-electrode according to a first embodiment;

FIG. 7 is a cross-sectional view schematically showing a process of fabricating a solar cell;

FIG. 8 is a cross-sectional view schematically showing a process of fabricating a solar cell in the y direction;

FIG. 9 is a cross-sectional view schematically showing a process of fabricating a second conductive-type region of a solar cell in the x direction;

FIG. 10 is a cross-sectional view schematically showing a process of fabricating a first conductive-type region of a solar cell in the x direction;

FIG. 11 is a cross-sectional view schematically showing a process of fabricating a solar cell in the y direction;

FIG. 12 is a cross-sectional view schematically showing a process of fabricating a second conductive-type region of a solar cell in the x direction;

FIG. 13 is a cross-sectional view schematically showing a process of fabricating a first conductive-type region of a solar cell in the x direction;

FIG. 14 is a cross-sectional view schematically showing a process of fabricating a solar cell in the y direction;

FIG. 15 is a cross-sectional view schematically showing a process of fabricating a first conductive-type region of a solar cell in the x direction;

FIG. 16 is a cross-sectional view schematically showing a process of fabricating a solar cell in the y direction;

FIG. 17 is a cross-sectional view schematically showing a process of fabricating a second conductive-type region of a solar cell in the x direction;

FIG. 18 is a cross-sectional view schematically showing a process of fabricating a first conductive-type region of a solar cell in the x direction;

FIG. 19 is a cross-sectional view schematically showing a process of fabricating a solar cell in the y direction;

FIG. 20 is a cross-sectional view schematically showing a process of fabricating a second conductive-type region of a solar cell in the x direction;

FIG. 21 is a cross-sectional view schematically showing a process of fabricating a first conductive-type region of a solar cell in the x direction;

FIG. 22 is a cross-sectional view schematically showing a process of fabricating a second conductive-type region of a solar cell in the x direction;

FIG. 23 is a cross-sectional view schematically showing a process of fabricating a first conductive-type region of a solar cell in the x direction;

FIG. 24 is a plane view showing a solar cell according to a comparative example;

FIG. 25 is a plane view showing a solar cell according to a second embodiment;

FIG. 26 is a cross-sectional view showing a structure of a solar cell according to a second embodiment; and

FIG. 27 is a plane view showing a solar cell according to a modification.

### DETAILED DESCRIPTION

The invention will now be described by reference to the preferred embodiments. This does not intend to limit the scope of the present invention, but to exemplify the invention.

Hereinbelow, the preferred embodiments will be described with reference to the accompanying drawings. Note that in all of the Figures the same reference numerals are given to the same components and the repeated description thereof is omitted as appropriate.

The present invention will be outlined before it is explained in detail. Embodiments of the present invention relate to a back-contact type solar cell where electrodes by which to extract the electric power generated by the solar cell are provided on a back surface of the solar cell, which is disposed opposite a light-receiving surface on which light mainly enters. In the back-contact solar cell, an n-type region and a p-type region are, for example, arranged alternately on the back surface in a first direction. An n-side electrode or a p-side electrode are provided on each of the regions. The n-side electrode and the p-side electrode extend in a second direction that intersects with the first direction.

The solar cell according to the present embodiments is configured such that a photoelectric conversion unit of the solar cell is divided into a plurality of sub-cells and such that a separation region is provided on a boundary between the adjacent sub-cells. Two adjacent sub-cells are connected in series by electrodes provided across these two adjacent sub-cells. In the present embodiments, dividing each solar cell into a plurality of sub-cells allow the lengths of the n-side electrode and the p-side electrode extending in the second direction to be reduced, so that the resistance of collecting electrodes is lowered. Lowering the resistance of current collecting electrodes can enhance the current collecting efficiency of a back surface electrode. Also, in the present embodiments, the solar cell where a plurality of sub-cells are connected in series with each other is integrally formed. Thus, compared with the case where each sub-cell is separately formed before the plurality of such sub-cells are connected by wirings and the like, the manufacturing cost can be reduced in the present embodiments.

In the solar cell according to the present embodiments, the solar cell is divided into sub-cells such that the light-receiving area differs in between a sub-cell provided at one end of a plurality of sub-cells and a sub-cell provided at the other end thereof. In the back-contact solar cell, when a first conductive-type region (e.g., the n-type region) and a second conductive-type region (e.g., the p-type region) are formed on a first conductive-type region having a first conductivity type (e.g., n-type), a p-n junction is provided in the second conductive-type region. At this time, carriers (electrons and holes) generated by the incident light are isolated in the second conductive-type region where the p-n junction is provided. Thus, the carrier extraction efficiency at a first electrode connected to the first conductive-type region is possibly lower than that at a second electrode connected to the second conductive-type region. In the light of this, according to the present embodiments, the area of sub-cell where the first electrode is provided is set larger than that where the second electrode is provided, so that the amount of carriers extracted from the first electrode is equalized to that extracted from the second and vice versa. Thereby, the amount of current outputted respectively from a plurality of sub-cells are equalized to each other and the output characteristics of the solar cells as a whole are improved.

### First Embodiment

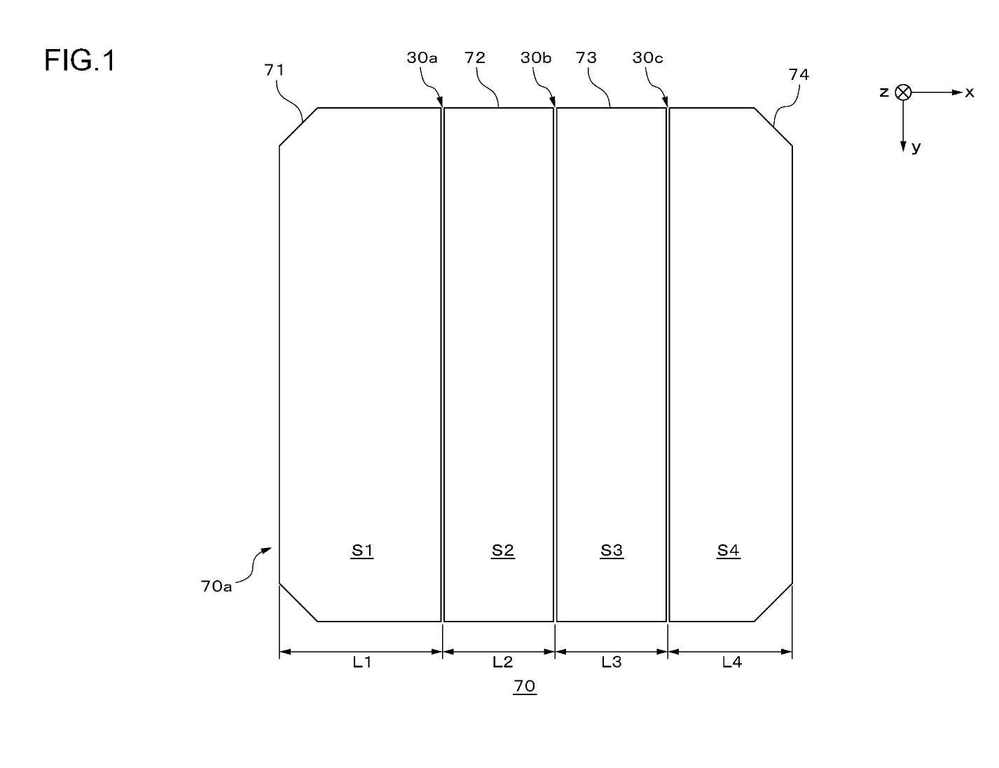

A detailed description is given of a solar cell 70 according to a first embodiment, using FIG. 1 to FIG. 6.

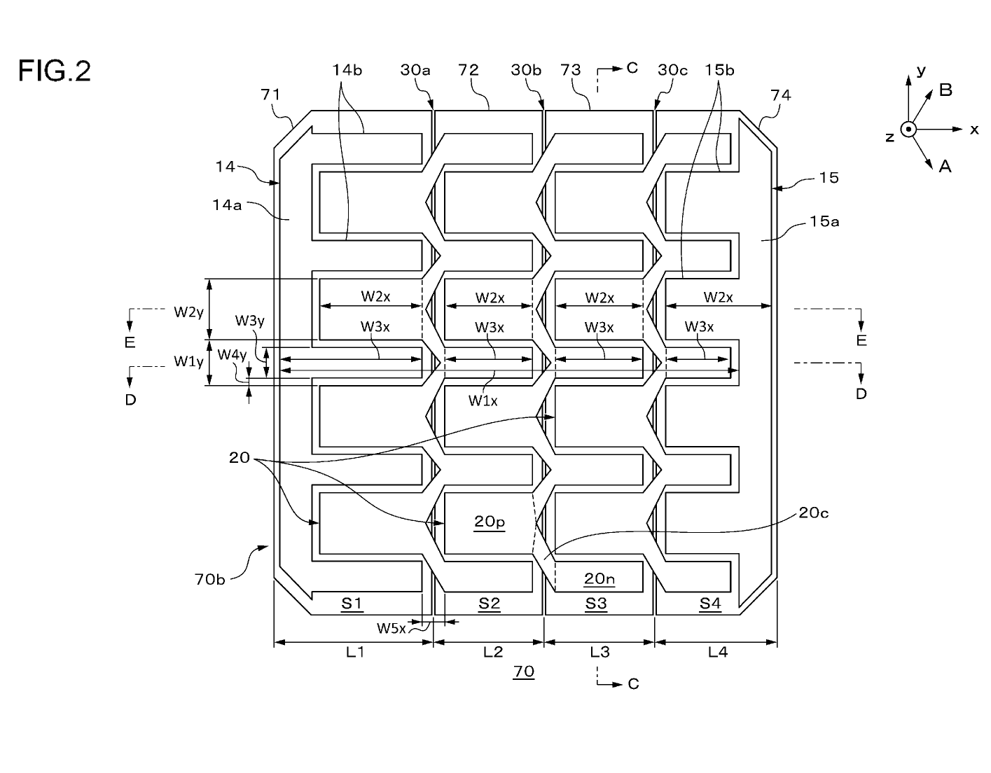

FIG. 1 and FIG. 2 are each a plane view showing the solar cell 70 according to a first embodiment. FIG. 1 shows light-receiving surfaces 70a of the solar cell 70, and FIG. 2 shows a back surface 70b of the solar cell 70.

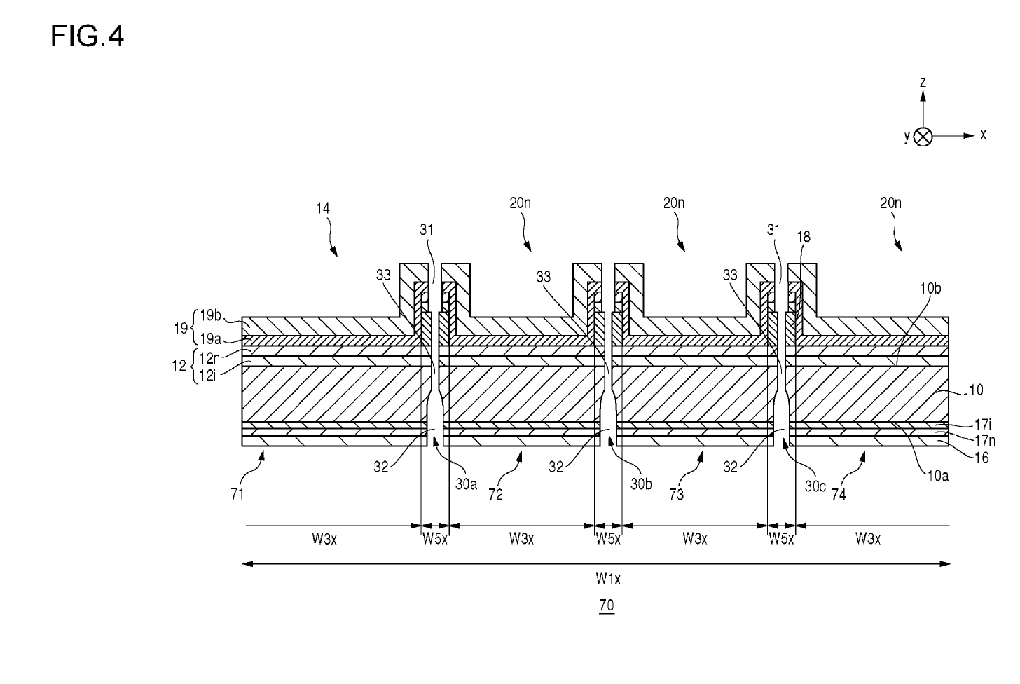

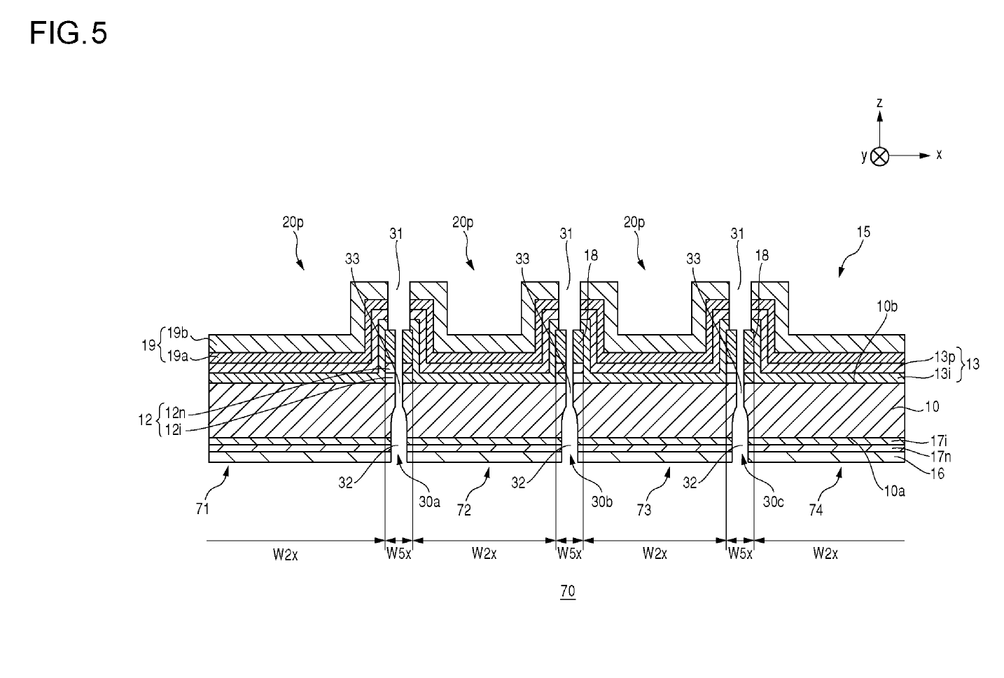

As shown in FIG. 1, the solar cell 70 comprises a plurality of sub-cells 71 to 74. The plurality of sub-cells 71 to 74 are demarcated by splits formed on boundaries 30a to 30c (hereinafter generically referred to as “boundary 30” or “boundaries 30”, also) that extend in the first direction (y direction), and are arranged side by side in the second direction (x direction) that intersects with the first direction. The plurality of sub-cells 71 to 74 are arranged in this order along the x direction. A detailed description will be later given of the boundaries 30 between the sub-cells, using FIG. 4 and FIG. 5.

As shown in FIG. 2, the solar cell 70 includes a first electrode 14, a second electrode 15, and a sub-electrode 20, which are provided on the back surface 70b.

The first electrode 14 is formed in a comb teeth shape by including a bus-bar electrode 14a, which extends in the y direction, and a plurality of finger electrodes 14b, which extend in the x direction. The first electrode 14 is formed in a first sub-cell 71. The second electrode 15 are formed in a comb teeth shape by including a bus-bar electrode 15a, which extends in the y direction, and a plurality of finger electrodes 15b, which extend in the x direction; the second electrode 15 is formed in a fourth sub-cell 74.

A sub-electrode 20 has a first sub-electrode portion 20n, a second sub-electrode portion 20p and a connector 20c. The sub-electrode 20 is so provided as to lie across adjacent sub-cells, and connects the first conductive-type region in one of the adjacent sub-cells and the second conductive-type region in the other thereof. For example, a sub-electrode 20 connecting the second sub-cell 72 and the third sub-cell 73 is constituted by a first sub-electrode portion 20n, which is formed on the first conductive-type region of the third sub-cell 73, a second sub-electrode portion 20p, which is formed on the second conductive-type region of the second sub-cell 72, and a connector 20c, which connects the first sub-electrode portion 20n and the second sub-electrode portion 20p. The connector 20c is so arranged as to lie across the boundary between the second sub-cell 72 and the third sub-cell 73.

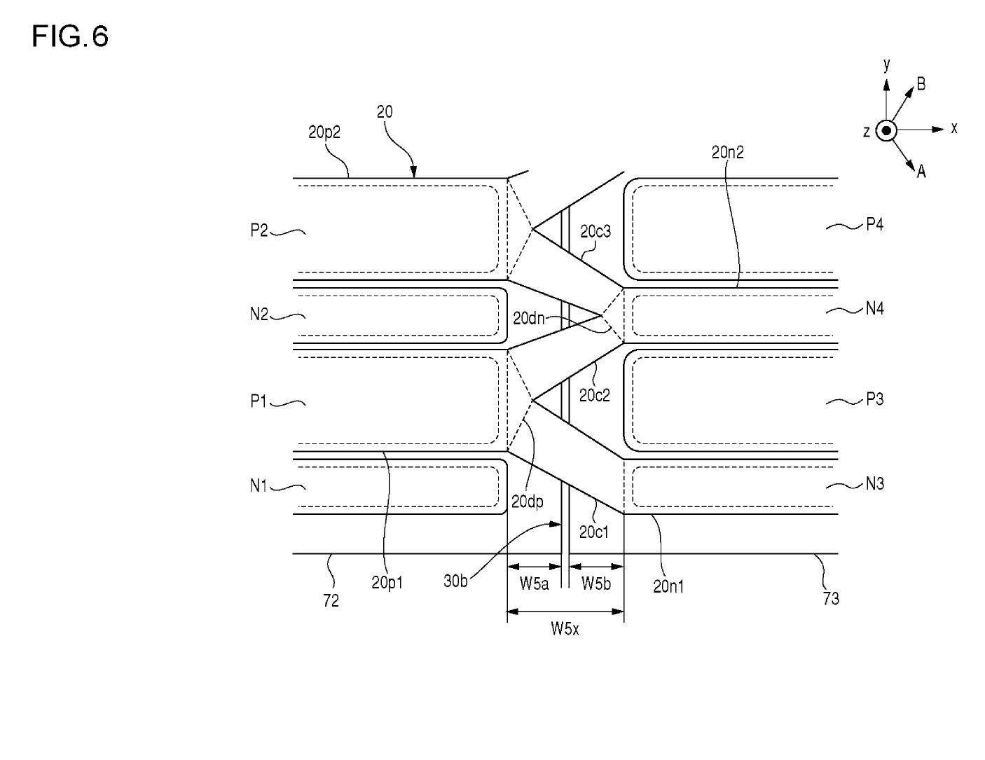

The connector 20c extends in directions A and B, which are tilted relative to the x direction, and the sub-electrode 20 has a branched structure which is branched out into one connector 20c extending in the direction A and the other connector 20c extending in the direction B. The branched structure where the connectors 20c extend obliquely will be described later using FIG. 6.

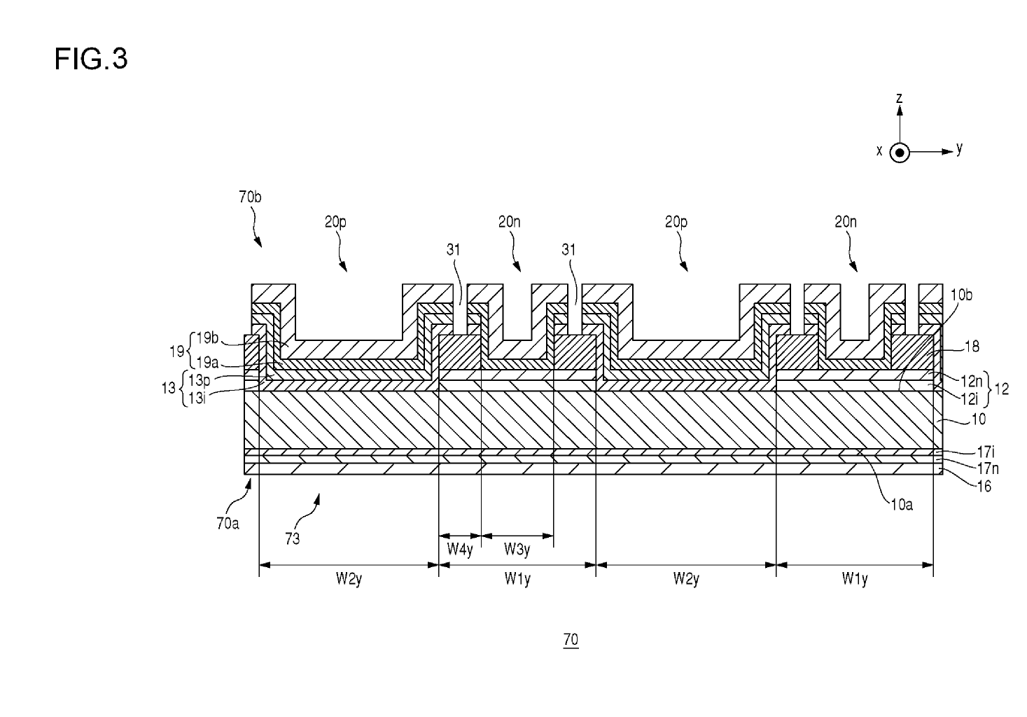

The first electrode 14 and the first sub-electrode portion 20n are provided in a third region W3x and W3y inside a first region W1x and W1y corresponding to the first conductive-type region. On the other hand, the second electrode 15 and the second sub-electrode portion 20p are provided in a second region W2x and W2y corresponding to the second conductive-type region. A fourth region W4y, which isolates between the first conductive-type region and the second conductive-type region in the y direction, is provided between a second region W2y and a third region W3y. An isolation groove, which isolates between a sub-electrode 20 and the first electrode 14, the second electrode 15 or another sub-electrode 20, is formed in the fourth region W4y. A detailed description will be later given of the isolation groove, using FIG. 3.

Also, a separation region W5x is provided between adjacent sub-cells, and the boundaries 30a to 30c between the sub-cells are located in the separation regions W5x. A detailed description will be later given of the separation region W5x, using FIG. 4 and FIG. 5.

As shown in FIG. 1 and FIG. 2, in the present embodiment, the plurality of sub-cells 71 to 74 are made to differ in their sizes. More specifically, an area S1 of a main surface (the light-receiving surface or the back surface) of the first sub-cell 71 where the first electrode 14 is provided is larger than an area S4 of a main surface of the fourth sub-cell 74 where the second electrode 15 is provided. Also, areas S2 and S3 of the second sub-cell 72 and the third sub-cell 73, respectively, which are positioned between the first sub-cell 71 and the fourth sub-cell 74, are each smaller than the area S1 of a main surface of the first sub-cell 71. Thus the area S1 of the first sub-cell 71 is the largest among the plurality of sub-cells 71 to 74.

In the present embodiment, the lengths of the plurality of sub-cells 71 to 74 in the y direction are all equal and therefore the sizes of the areas S1 to S4 are determined respectively by the lengths L1 to L4 of the sub-cells 71 to 74 in the x direction. Thus the length L1 of the first sub-cell 71 in the x direction is the longest.

Of the plurality of sub-cells 71 to 74, the first sub-cell 71 with the first electrode 14 and the fourth sub-cell 74 with the second electrode 15 are provided with the electrodes by which to extract the electric power to the exterior of the solar cell 70. Hence, the first sub-cell 71 and the fourth sub-cell 74 are hereinafter referred to as “extraction sub-cells” also. Of the plurality of sub-cells 71 to 74, the sub-cells positioned between the extraction sub-cells 71 and 74 are hereinafter referred to as “intermediate sub-cells” also.

FIG. 3 is a cross-sectional view, taken along the line C-C of FIG. 2, showing a structure of the solar cell 70 according to the first embodiment. FIG. 3 shows a cross-sectional structure of the third sub-cell 73, and the other sub-cells have the same or similar structure as that shown in FIG. 3.

The solar cell 70 includes a semiconductor substrate 10, a first conductive-type layer 12n, a first i-type layer 12i, a second conductive-type layer 13p, a second i-type layer 13i, a first insulating layer 16, a third conductive-type layer 17n, a third i-type layer 17i, a second insulating layer 18, and an electrode layer 19. The electrode layer 19 constitutes the first electrode 14, the second electrode 15 or the sub-electrode 20. The solar cell 70 is a back-contact solar cell where an amorphous semiconductor film is formed on a monocrystalline (single-crystal) or polycrystalline semiconductor substrate.

The semiconductor substrate 10 has a first main surface 10a, which is provided on a light-receiving surface 70a side, and a second main surface 10b, which is provided on a back surface 70b side. The semiconductor substrate 10 absorbs the light incident on the first main surface 10a and generates electrons and holes as carriers. The semiconductor substrate 10 is constituted by a crystalline semiconductor substrate of an n-type or p-type conductivity type. Specifically, the crystalline semiconductor substrate as used herein may be, for example, a crystalline silicon (Si) such as a single-crystal silicon substrate and a polycrystalline silicon substrate.

The present embodiment illustrates a case where the semiconductor substrate 10 is constituted by an n-type single-crystal silicon substrate. Note that the a semiconductor substrate other than the single-crystal semiconductor substrate may be used as the semiconductor substrate. For example, a compound semiconductor formed of compound materials like gallium arsenide (GaAs) and indium phosphide (InP) may be used as the semiconductor substrate.

Here, the light-receiving surface 70a means one main surface through which light (sunlight) mainly enters and is specifically a surface through which the majority of light incident on the solar cell 70 enters. The back surface 70b, on the other hand, means the other main surface located opposite to the light-receiving surface 70a.

The third i-type layer 17i, which is constituted by a substantially intrinsic amorphous semiconductor (hereinafter, an intrinsic semiconductor will be referred to as “i-type semiconductor” also), is provided on the first main surface 10a of the semiconductor substrate 10. In the present embodiment, the third i-type layer 17i is formed of i-type amorphous silicon containing hydrogen (H). The thickness of the third i-type layer 17i is not particularly limited to any value as long as the thickness thereof is of a value that contributes substantially nothing to the power generation. The thickness of the third i-type layer 17i may be about several Å to about 250 Å, for instance.

Note that in the present embodiment the “amorphous semiconductor” includes a microcrystalline semiconductor. The microcrystalline semiconductor is a semiconductor such that an average particle diameter of crystal grains in the amorphous semiconductor is in a range of 1 nm to 50 nm.

The third conductive-type layer 17n having the same conductivity type as that of the semiconductor substrate 10 is formed on the third i-type layer 17i. The third conductive-type layer 17n, in which an n-type impurity is doped, is an amorphous semiconductor layer having an n-type conductivity type. In the present embodiment, the third conductive-type layer 17n is formed of n-type amorphous silicon containing hydrogen. The thickness of the third conductive-type layer 17n is not particularly limited to any value. The thickness of the third conductive-type layer 17n may be about 20 Å to about 500 Å, for instance.

The first insulating layer 16, having the functions of an antireflection coating (film) and a protective film, is formed on the third conductive-type layer 17n. The first insulating layer 16 may be formed of silicon dioxide (SiO₂), silicon nitride (SiN), silicon oxynitride (SiON) or the like, for instance. The thickness of the first insulating layer 16 may be set, as appropriate, depending on antireflection properties of the antireflection coating or the like. The thickness of the first insulating layer 16 may be about 80 nm to about 1 μm, for instance.

The aforementioned third i-type layer 17i and third conductive-type layer 17n each has the function of a passivation layer for the semiconductor substrate 10. Also, a layered structure of the first insulating layer 16 has the function of an antireflection film for coating the semiconductor substrate 10. The structure of the passivation layer provided on the first main surface 10a of the semiconductor substrate 10 is not limited to this. For example, the structure may be such that silicon dioxide is formed on the first main surface 10a of the semiconductor substrate 10 and then silicon nitride is formed thereon.

A first layered product 12 and a second layered product 13 are formed on the second main surface 10b of the semiconductor substrate 10. The first layered products 12 and the second layered products 13 are arranged alternately in the y direction. Thus, the first region W1y, where the first layered product 12 is provided, and the second region W2y, where the second layered product 13 are provided, are arranged alternately along the y direction. Also, the first layered product 12 and the second layered product 13, which are placed adjacent to each other in the y direction, are provided such that the first layered product 12 and the second layered product 13 are in contact with each other. Hence, in the present embodiment, the second main surface 10b are substantially covered entirely with the first layered product 12 and the second layered product 13.

The first layered product 12 is constituted by a stacked body comprised of the first i-type layer 12i, formed on the second main surface 10b, and the first conductive-type layer 12n, formed on the first i-type layer 12i. Similar to the above-described third i-type layer 17i, the first i-type layer 12i is formed of i-type amorphous silicon containing hydrogen. The thickness of the first i-type layer 12i is not particularly limited to any value as long as the thickness thereof is of a value that contributes substantially nothing to the power generation. The thickness of the first i-type layer 12i may be about several Å to about 250 Å, for instance.

Similar to the above-described third conductive-type layer 17n, the first conductive-type layer 12n is doped with an n-type impurity; similar to the semiconductor substrate 10, the first conductive-type layer 12n has the n-type conductivity type. More specifically, in the present embodiment, the first conductive-type layer 12n is formed of n-type amorphous silicon containing hydrogen. The thickness of the first conductive-type layer 12n is not particularly limited to any value. The thickness of the first conductive-type layer 12n may be about 20 Å to about 500 Å, for instance.

The second insulating layer 18 is formed on the first layered product 12. The second insulating layer 18 is not provided in the third region W3y, corresponding to a central portion of the first region W1y in the y direction, but provided in the fourth region W4y, corresponding to both ends of the third region W3y in the first region W1y. The width of the third region W3y is preferably wider in the following sense. That is, for example, the width of the third region W3y may be set in such a range that the width thereof is larger than ⅓ of the width of the first region W1y and less than that of the first region W1y.

The material used for the second insulating layer 18 is not particularly limited. The second insulating layer 18 may be formed of silicon dioxide, silicon nitride, silicon oxynitride or the like, for instance. Among them, the second insulating layer 18 is preferably formed of silicon nitride. Also, the second insulating layer 18 preferably contains hydrogen.

The second layered product 13 is formed on the second region W2y of the second main surface 10b, where the first layered product 12 is not provided, and ends of the fourth region W4y thereof, where the second insulating layer 18 is provided. Thus, both ends of the second layered product 12 are provided such that the both ends thereof overlap with the first layered product 12 in a height direction (the z direction).

The second layered product 13 is constituted by a stacked body comprised of the second i-type layer 13i, formed on the second main surface 10b, and the second conductive-type layer 13p, formed on the second i-type layer 13i.

The second i-type layer 13i is formed of i-type amorphous silicon containing hydrogen. The thickness of the second i-type layer 13i is not particularly limited to any value as long as the thickness thereof is of a value that contributes substantially nothing to the power generation. The thickness of the second i-type layer 13i may be about several Å to about 250 Å, for instance.

The second conductive-type layer 13p is doped with a p-type impurity and is an amorphous semiconductor layer having the p-type conductivity type. More specifically, in the present embodiment, the second conductive-type layer 13p is formed of p-type amorphous silicon containing hydrogen. The thickness of the second conductive-type layer 13p is not particularly limited to any value. The thickness of the second conductive-type layer 13p may be about 20 Å to about 500 Å, for instance.

As described above, the second i-type layer 13i, whose thickness contributes substantially nothing to the power generation, is provided between the crystalline semiconductor substrate 10 and the second conductive-type layer 13p. By employing such a structure as this, the recombination of carriers at the bonded interface of the semiconductor substrate 10 and the second layered product 13 can be suppressed. This can help improve the photoelectric conversion efficiency. In the present embodiment, an exemplary solar cell is shown where amorphous silicon having the p-type or n-type conductivity type is formed on the crystalline semiconductor substrate so as to form a p-n junction. However, this should not be considered as limiting and, for example, a solar cell may be used where an impurity is diffused into the crystalline semiconductor substrate so as to form a p-n junction.

In the present embodiment, the photoelectric conversion unit is constituted by the semiconductor substrate 10, the first layered product 12 and the second layered product 13. The first region W1y, where the semiconductor substrate 10 and the first layered product 12 are in contact with each other, is the first conductive-type region; the second region W2y, where the semiconductor substrate 10 and the second layered product 13 are in contact with each other, is the second conductive-type region.

In the present embodiment, the semiconductor substrate having the n-type conductivity type is used as the semiconductor substrate 10. Thus, the electrons are majority carriers, whereas the holes are minority carriers. For this reason, in the present embodiment, the width of the second region W2y, where the minority carriers are collected, is set larger than that of the third region W3y, where the majority carriers are collected. This therefore increases the power generation efficiency.

The first sub-electrode portion 20n, which collects electrons, among the sub-electrodes 20 is formed on the first conductive-type layer 12n. Also, the second sub-electrode portion 20p, which collects holes, among the sub-electrodes 20 is formed on the second conductive-type layer 13p. An isolation groove 31 is formed between the first sub-electrode portion 20n and the second sub-electrode portion 20p. Thus, the first sub-electrode portion 20n and the second sub-electrode portion 20p formed on the same sub-cell are separated by the isolation groove 31, so that the electric resistance between the both electrode portions becomes high or the both electrode portions are electrically insulated from each other.

As for the first sub-cell 71, the first electrode 14, instead of the first sub-electrode portion 20n, is formed on the first conductive-type layer 12n. As for the fourth sub-cell 74, the second electrode 15, instead of the second sub-electrode portion 20p, is formed on the second conductive-type layer 13p. In this case, the first electrode 14 and the sub-electrode 20 are separated by the isolation groove 31; similarly, the second electrode 15 and the sub-electrode 20 are separated by the isolation groove 31.

In the present embodiment, an electrode layer 19 is constituted by a layered product composed of two conductive layers, which are a first conductive layer 19a and a second conductive layer 19b. The first conductive layer 19a is formed of a transparent conductive oxide (TCO) where, for example, tin oxide (SnO₂), zinc oxide (ZnO), indium oxide (In₂O₃) or the like is doped with tin (Sn), antimony (Sb), fluorine (F), aluminum (Al) or the like.

The first conductive layer 19a is a transparent electrode layer formed of indium tin oxide (ITO). The thickness of the first conductive layer 19a may be about 50 to about 200 nm, for instance. In the present embodiment, the first conductive layer 19a is formed by using a thin film forming method such as sputtering, chemical vapor deposition (CVD) and vapor deposition.

The second conductive layer 19b is a metal electrode layer containing a metal such as copper (Cu) or tin (Sn). However, this should not be considered as limiting, and the second conductive layer 19b may be formed of a metal or conductive material, other than the aforementioned ones, such as gold (Au) or silver (Ag), or combination thereof. In the present embodiment, the second conductive layer 19b has a three-layer structure where a copper layer and a tin layer formed by using a plating method are stacked on a copper ground layer formed by using the sputtering. The thicknesses of the three layers may be about 50 nm to about 1 μm (the copper ground layer), about 10 μm to about 30 μm (the copper layer on the ground layer), and about 1 μm to about 5 μm (the tin layer on the copper layer), respectively.

Note that the structure of the electrode layer 19 is not limited to the layered product comprised of the first conductive layer 19a and the second conductive layer 19b. Instead, for example, the structure of the electrode layer 19 may be such that the first conductive layer 19a formed of a transparent conductive oxide is not provided at all and only the second conductive layer 19b formed of a metal is provided.

FIG. 4 is a cross-sectional view, taken along the line D-D of FIG. 2, showing a structure of the first conductive-type region of the solar cell 70 in the x direction. FIG. 5 is a cross-sectional view, taken along the line E-E of FIG. 2, showing a structure of the second conductive-type region of the solar cell 70 in the x direction.

In the solar cell 70, the first conductive-type regions or the second conductive-type regions are continuously provided in the x direction, where the plurality of sub-cells 71 to 74 are arranged, with the separation region W5x being held therebetween. In a cross section along the line D-D, as shown in FIG. 4, the third region W3x, which is the first conductive-type region, and the separation region W5x, where the second insulating layer 18 is provided, are arranged alternately in the x direction. Similarly, in a cross section along the line E-E, as shown in FIG. 5, the second region W2x, which is the second conductive-type region, and the separation region W5x, where the second insulating layer 18 is provided, are arranged alternately in the x direction. Thus, the first conductive-type region, provided in one of adjacent sub-cells, and the second conductive-type region, provided in the other thereof, are arranged such that they are not aligned in the y direction. As a result, the connectors 20c, which connect the first sub-electrode portion 20n provided on the first conductive-type region and the second sub-electrode portion 20p provided on the second conductive-type region, do not extend in the x direction but extend in the direction A and the direction B, which are tilted relative to the x direction.

FIG. 4 and FIG. 5 each shows structures of the boundaries 30a, 30b and 30c that divide the solar cell 70 into the plurality of sub-cells 71 to 74. The boundaries 30a to 30c are provided in the separation regions W5x where the second insulating layers 18 are formed. Splits that segmentalize the plurality of sub-cells 71 to 74 are formed in these respective boundaries 30a to 30c; each split has an isolation groove 31, a temporary groove 32, and an insulation split 33. The isolation groove 31 is formed on the back surface 70b, divides the electrode layer 19, and electrically insulates between adjacent electrodes. The temporary groove 32 has a depth reaching midway through the thickness of the semiconductor substrate 10 from the light-receiving surface 70a. The temporary groove 32 is a groove formed for the purpose of forming the insulation split 33 and is formed, for example, by laser irradiation applied to the light-receiving surface 70a.

The insulation split 33, which is a split passing through the semiconductor substrate 10, prevents carriers (i.e., electrons or holes) from moving between the adjacent sub-cells. Thus, the insulation split 33 functions as an insulating portion that makes high the electric resistance, between the photoelectric conversion unit of one of the adjacent sub-cells and the photoelectric conversion unit of the other thereof, or insulates between those photoelectric conversion units. Provision of such grooves and splits as described above electrically isolates the first conductive-type region provided in one of the adjacent sub-cells and the second conductive-type region provided in the other thereof and thereby enhances the efficiency of collecting the carriers generated. The insulation split 33 is formed by, for example, bending the semiconductor substrate 10 such that the temporary groove 32 is a starting point. In this case, the insulation split 33 may run through the first layered product 12 and the second insulating layer 18 provided on the second main surface 10b of the semiconductor substrate 10.

The temporary groove 32 and the insulation split 33 may be formed integrally with each other by using another method. For example, the insulation split 33 running through the semiconductor substrate 10 may be formed by using the following processing. That is, a dicing processing is used where the semiconductor substrate 10 is cut from a light-receiving surface 70a side by using a rotary blade or the like. Or, a sandblast treatment or an etching process is performed on the light-receiving surface 70a covered with a mask placed thereon.

In the separation region W5x, no isolation grooves 31 is formed in a region where the connectors 20c of the sub-electrode 20 is provided. The semiconductor substrate 10 is bent after the electrode layer 19 has been formed. This cuts only the semiconductor layer so as to form the insulation split 33; however, the metal layer (e.g., the second conductive layer 19b) remains connected without being cut. In the present embodiment, used is copper that is a material having a high ductility or spreadability. Thus, the insulation split 33 is formed such that at least the second conductive layer 19b is kept intact, and the remaining electrode layer 19 becomes the connectors 20c of the sub-electrode 20.

FIG. 6 is a plane view showing a structure of sub-electrodes 20. FIG. 6 shows the sub-electrode 20 that connects between the second sub-cell 72 and the third sub-cell 73.

For convenience of explanation, the first conductive-type regions and the second conductive-type regions, which are arranged alternately in a positive (+) y direction in the second sub-cell 72, are called a first first-conductive-type region N1, a first second-conductive-type region P1, a second first-conductive-type region N2, and a second second-conductive-type region P2 in order from the bottom of FIG. 6. Similarly, the first conductive-type regions and the second conductive-type regions, which are arranged alternately in the positive (+) y direction in the third sub-cell 73, are called a third first-conductive-type region N3, a third second-conductive-type region P3, a fourth first-conductive-type region N4, and a fourth second-conductive-type region P4 in order from the bottom thereof.

The sub-electrode 20 has a plurality of first sub-electrode portions 20n1 and 20n2, a plurality of second sub-electrode portions 20p1 and 20p2, a plurality of connectors 20c1, 20c2 and 20c3, a first sub-electrode-side branched portion 20dn, and a second sub-electrode-side branched portion 20dp.

A first second-sub-electrode portion 20p1 is provided on the first second-conductive-type region P1 of the second sub-cell 72, and a second second-sub-electrode portion 20p2 is provided on the second second-conductive-type region P2 of the second sub-cell 72. A first first-sub-electrode portion 20n1 is provided on the third first-conductive-type region N3 of the third sub-cell 73, and a second first-sub-electrode portion 20n2 is provided on the fourth first-conductive-type region N4 of the third sub-cell 73.

A first connector 20c1 connects the first second-sub-electrode portion 20p1 of the second sub-cell 72 and the first first-sub-electrode portion 20n1 of the third sub-cell 73. Thus, the first connector 20c1 extends in the direction A between the positive (+) x direction and the negative (−) y direction (in a right obliquely downward direction as shown in FIG. 6). A second connector 20c2 connects the first second-sub-electrode portion 20p1 of the second sub-cell 72 and the second first-sub-electrode portion 20n2 of the third sub-cell 73. Thus, the second connector 20c2 extends in the direction B between the positive (+) x direction and the negative (−) y direction (in a right obliquely upward direction as shown in FIG. 6). A third connector 20c3 connects the second second-sub-electrode portion 20p2 of the second sub-cell 72 and the second first-sub-electrode portion 20n2 of the third sub-cell 73. Thus, the third connector 20c3 extends in the direction A between the positive (+) x direction and the negative (−) y direction. In this manner, the connectors 20c1 to 20c3 extend in the oblique direction A or B, which intersects with both the x direction and the y direction, in the separation region W5x.

The second sub-electrode-side branched portion 20dp is of a branched structure such that the first second-sub-electrode portion 20p1 is branched out into the first connector 20c1 and the second connector 20c2. Through the medium of the second sub-electrode-side branched portions 20dp, the first second-conductive-type region P1 of the second sub-cell 72 is connected to both the third first-conductive-type region N3 and the fourth first-conductive-type region N4, which are both located adjacent to the third second-conductive-type region P3, of the third sub-cell 73, disposed opposite to the first second-conductive-type region P1.

The second sub-electrode-side branched portion 20dp is not placed in a region W5b, which is provided closer to the third sub-cell 73 toward which the branched connectors extend. Instead, the second sub-electrode-side branched portion 20dp is placed in a region W5a, which is provided closer to the second sub-cell 72 from which the branched structure starts to branch out. Thereby, the lengths of the first connector 20c1 and the second connector 20c2 can be made long. Making the branched connectors long allows the tension acting in the x direction to be effectively dispersed in the y direction. This can therefore enhance the effect of relaxing the tension in the branched structure.

The first sub-electrode-side branched portion 20dn is of a branched structure such that the second first-sub-electrode portion 20n2 is branched out into the second connector 20c2 and the third connector 20c3. Through the medium of the first sub-electrode-side branched portions 20dn, the fourth first-conductive-type region N4 of the third sub-cell 73 is connected to both the first second-conductive-type region P1 and the second second-conductive-type region P2, which are both located adjacent to the second first-conductive-type region N2, of the second sub-cell 72, disposed opposite to the fourth first-conductive-type region N4.

The first sub-electrode-side branched portion 20dn is not placed in the region W5a, which is provided closer to the second sub-cell 72 toward which the branched connectors extend. Instead, the first sub-electrode-side branched portion 20dn is placed in the region W5b, which is provided closer to the third sub-cell 73 from which the branched structure starts to branch out. Thereby, the lengths of the second connector 20c2 and the third connector 20c3 can be made long in the separation region W5x. Making the branched connectors long allows the tension acting in the x direction to be effectively dispersed in the y direction. This can therefore enhance the effect of relaxing the tension caused by the branched structure.

In the present embodiment, as shown in FIG. 2, first sub-electrode-side branched portion and the second sub-electrode-side branched portion are arranged alternately and thereby the sub-electrodes 20 are formed in zigzags. This can further enhance the effect of relaxing the tension acting on the sub-electrodes 20.

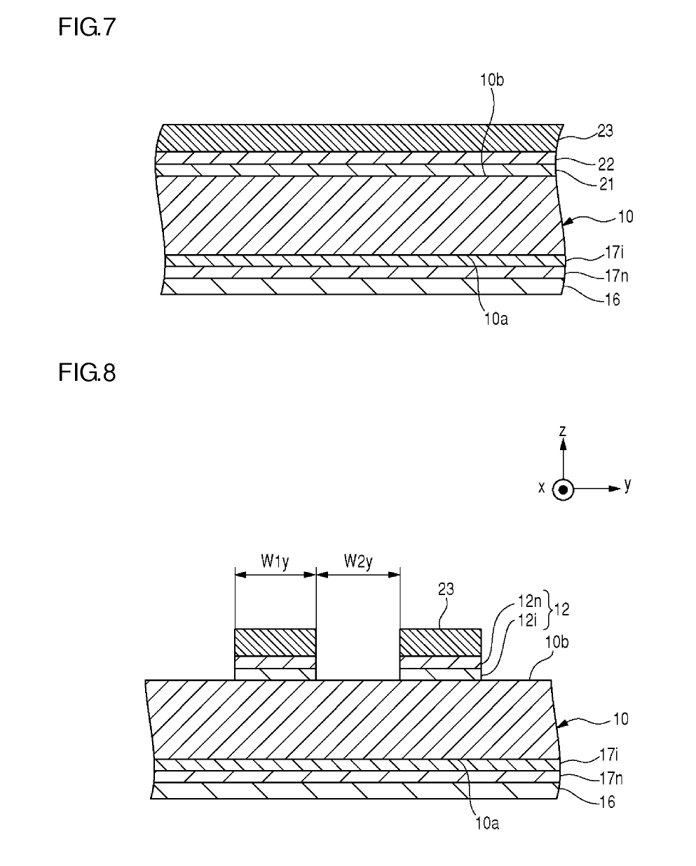

A description is now given of a method for fabricating the solar cell 70 according to the present embodiment by mainly referencing FIG. 7 to FIG. 23. Note that, in the present embodiment, the cross-section structure of the solar cell 70 differs depending on a direction. Thus, a description is given of the method for fabricating the solar cell 70 by showing an x-direction cross section corresponding to the cross section taken along the line C-C, a y-direction cross section corresponding to the cross section taken along the line D-D, and a y-direction cross section corresponding to the cross section taken along the line E-E.

A semiconductor substrate 10 as shown in FIG. 7 is first prepared, and the first main surface 10a and the second main surface 10b of the semiconductor substrate 10 are cleaned. The first main surface 10a and the second main surface 10b can be cleaned by using hydrofluoric acid (HF) aqueous solution or the like, for instance. A textured structure is preferably formed on the first main surface 10a by this cleaning process.

Then, an i-type amorphous semiconductor layer, which will become the third i-type layer 17i, an n-type amorphous semiconductor layer, which will becomes the third conductive-type layer 17n, and an insulating layer, which will become the first insulating layer 16, are formed on the first main surface 10a of the semiconductor substrate 10. Also, an i-type amorphous semiconductor layer 21, an n-type amorphous semiconductor layer 22 and an insulating layer 23 are formed on the second main surface 10b of the semiconductor substrate 10. Though the methods for forming the third i-type layer 17i, the third conductive-type layer 17n, the i-type amorphous semiconductor layer 21 and the n-type amorphous semiconductor layer 22, respectively, are not limited to any particular ones, the chemical vapor deposition (CVD) method such as a plasma CVD method can be used to form these layers. Though the method for forming the first insulating layer 16 and the insulating layer 23 is not limited to any particular one, a thin film forming method and the like such as the sputtering method and the CVD method can be used to form these layers.

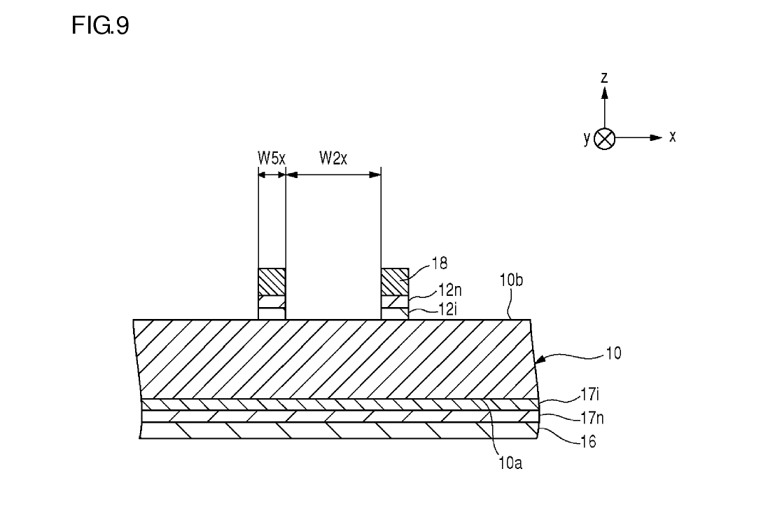

Then, as shown in FIG. 8 and FIG. 9, etching the insulating layer 23 partially removes the insulating layer 23. More specifically, during a subsequent process, a part of the insulating layer 23, the position of which corresponds to the second region W2x and W2y, where the p-type semiconductor layer is formed on the semiconductor substrate 10, is removed. Suppose that the insulating layer 23 is formed of silicon dioxide (SiO₂), silicon nitride (SiN) or silicon oxynitride (SiON). In this case, the etching of the insulating layer 23 can be done by using an acid etching solution such as HF aqueous solution while a resist mask is provided in a part of the insulating layer 23, the position of which corresponds to the first region W1y and W1x. FIG. 8 shows a cross-sectional view along the y direction and corresponds to a cross section taken along the line C-C of FIG. 2. FIG. 9 corresponds to a cross section, taken along the line E-E of FIG. 2, where the second conductive-type region is formed.

Then, using the patterned insulating layer 23 as a mask, the i-type amorphous semiconductor layer 21 and the n-type amorphous semiconductor layer 22 are etched by using an acid etching solution. The etching removes a part of the i-type amorphous semiconductor layer 21 and a part of the n-type amorphous semiconductor layer 22, their positions of which correspond to the second region W2y and W2x that is not covered with the insulating layer 23. Thereby, the second region W2y and W2x, where no insulating layer 23 is provided above the semiconductor substrate 10, is exposed on the second main surface 10b. The region where the first layered product remains intact becomes the first region W1y and W1x.

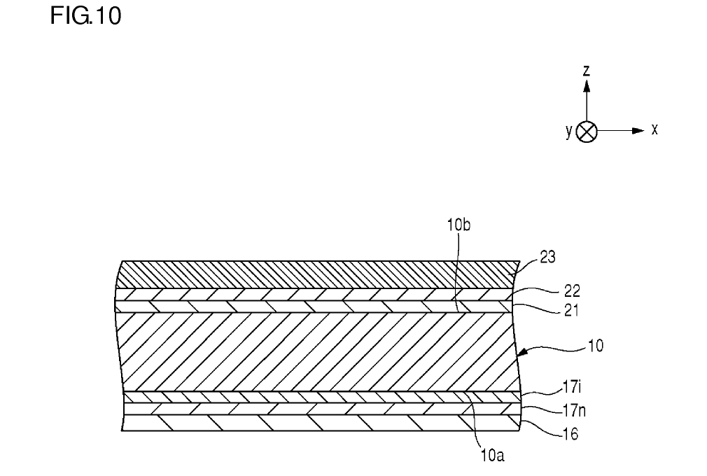

On the other hand, as shown in FIG. 10, the etching process is not performed on the i-type amorphous semiconductor layer 21, the n-type amorphous semiconductor layer 22 and the insulating layer 23, the positions of which correspond to the regions where the first conductive-type region is to be formed. FIG. 10 corresponds to a cross section, taken along the line D-D of FIG. 2, where the first conductive-type region is formed.

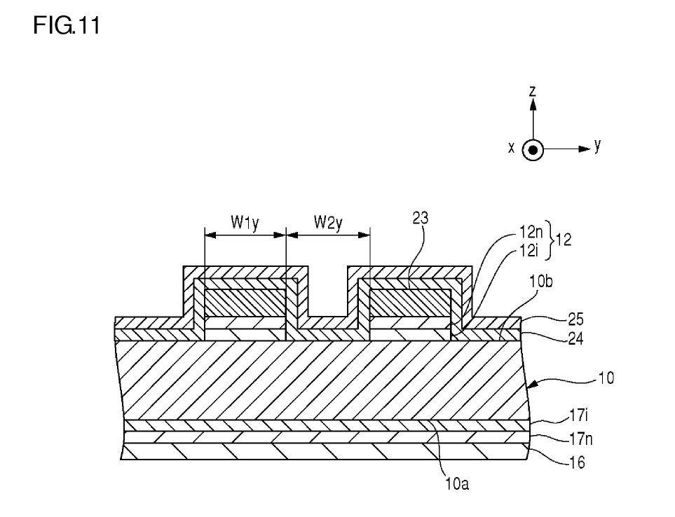

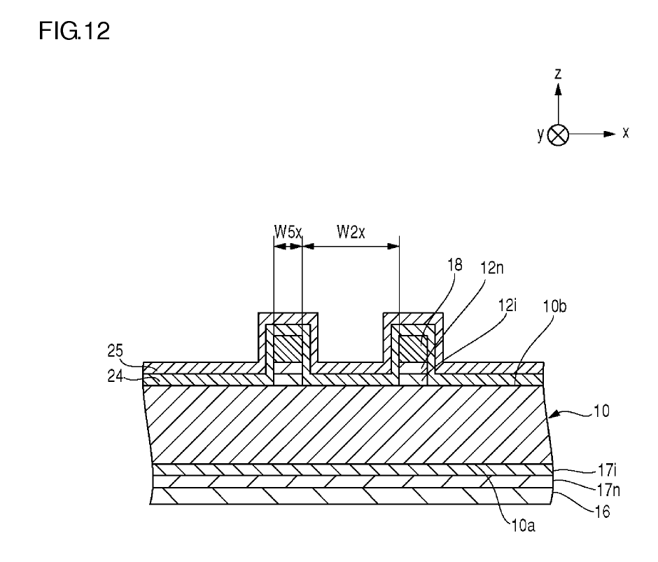

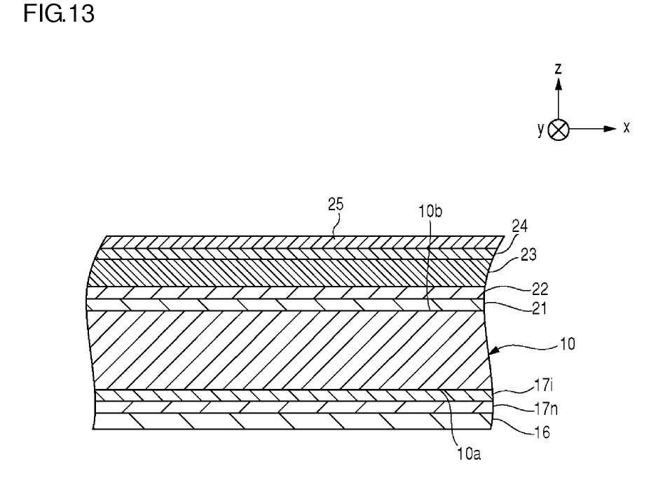

Then, as shown in FIG. 11, FIG. 12 and FIG. 13, an i-type amorphous semiconductor layer 24 is so formed as to cover the second main surface 10b, and a p-type amorphous semiconductor layer 25 is formed on the i-type amorphous semiconductor layer 24. Though the method for forming the i-type amorphous semiconductor layer 24 and the p-type amorphous semiconductor layer 25 is not limited to any particular one, a thin film forming method, such as the CVD method, and the like can be used to form these layers. FIG. 11 is an illustration showing a state in which the i-type amorphous semiconductor layer 24 and the p-type amorphous semiconductor layer 25 have been formed on the second main surface 10b shown in FIG. 8. FIG. 12 is an illustration showing a state in which the i-type amorphous semiconductor layer 24 and the p-type amorphous semiconductor layer 25 have been formed on the second main surface 10b shown in FIG. 9. FIG. 13 is an illustration showing a state in which the i-type amorphous semiconductor layer 24 and the p-type amorphous semiconductor layer 25 have been formed on the second main surface 10b shown in FIG. 10.

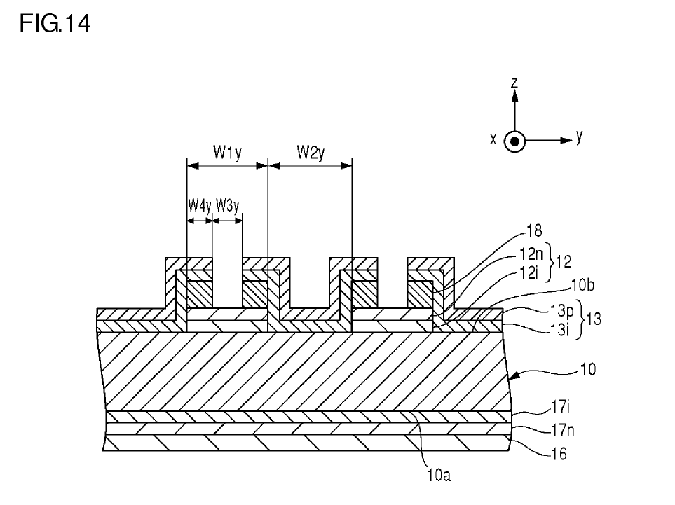

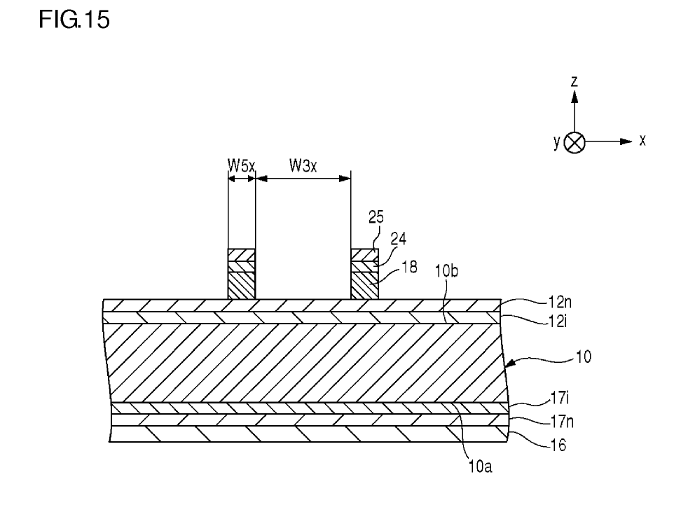

Then, as shown in FIG. 14 and FIG. 15, the insulating layer 23, the i-type amorphous semiconductor layer 24 and the p-type amorphous semiconductor layer 25 are partially etched. This forms the third region W3x, where a part of the insulating layer 23 is removed, and the separation region W5x, where a part of the insulating layer 23 remains intact and becomes the insulating layer 18. On the other hand, the etching process is not performed on the i-type amorphous semiconductor layer 24 and the p-type amorphous semiconductor layer 25, the positions of which correspond to the regions where the second conductive-type region shown in FIG. 12 is to be formed. FIG. 14 is an illustration showing a state in which the insulating layer 23, the i-type amorphous semiconductor layer 24 and the p-type amorphous semiconductor layer 25 shown in FIG. 11 have been etched. FIG. 15 is an illustration showing a state in which the insulating layer 23, the i-type amorphous semiconductor layer 24 and the p-type amorphous semiconductor layer 25 shown in FIG. 13 have been etched.

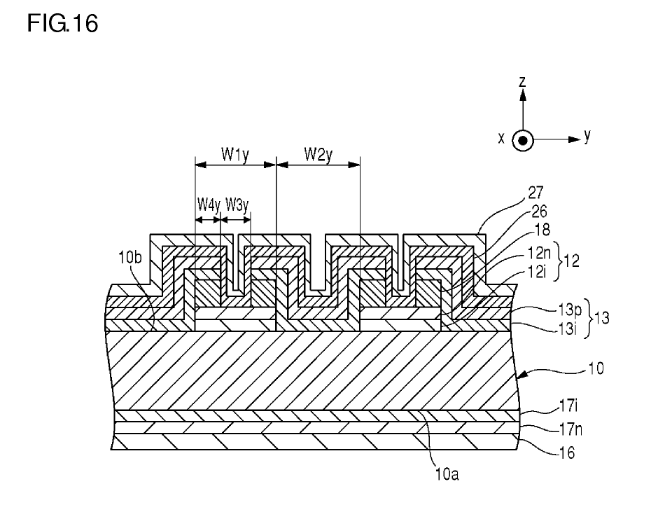

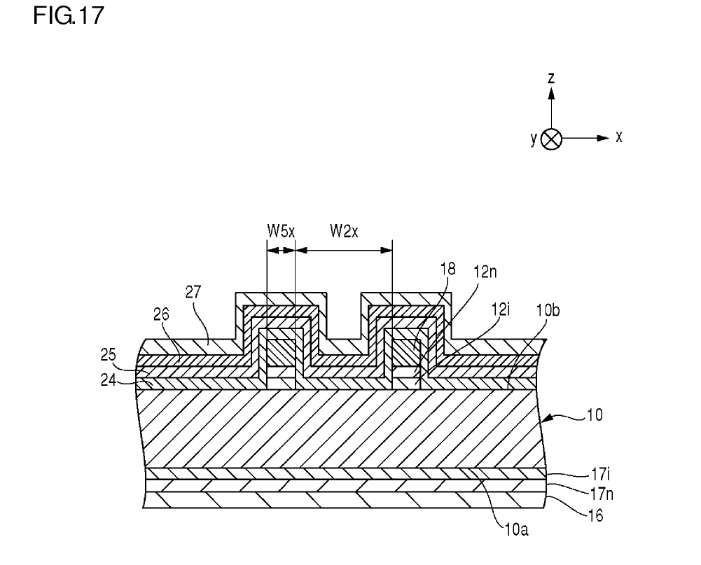

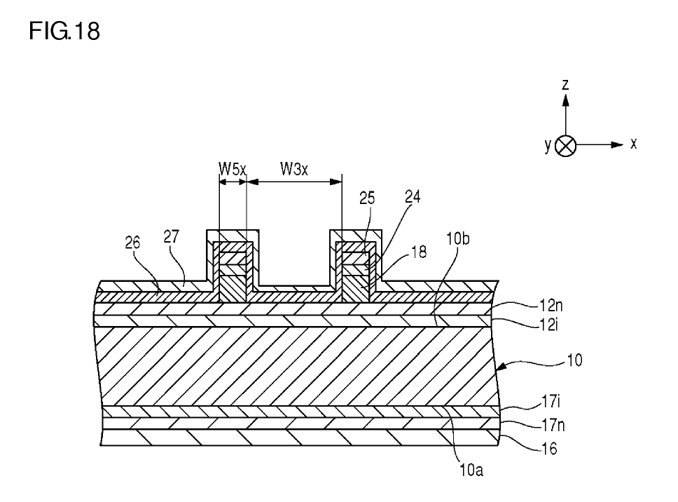

Then, as shown in FIG. 16, FIG. 17 and FIG. 18, conductive layers 26 and 27 are formed on the first conductive-type layer 12n and the second conductive-type layer 13p. The conductive layer 26 is a transparent electrode layer formed of indium tin oxide (ITO) or the like, and is a metal electrode layer constituted by a metal, such as copper (Cu) or an alloy. The conductive layers 26 and 27 are formed by using the CVD method, such as a plasma CVD method, or a thin film forming method, such as the sputtering method. In the conductive layer 27, an electrode may be formed, by using the plating method, on the metal electrode layer, which has been formed by using the thin forming method, so that the thickness of the electrode can be made thicker.

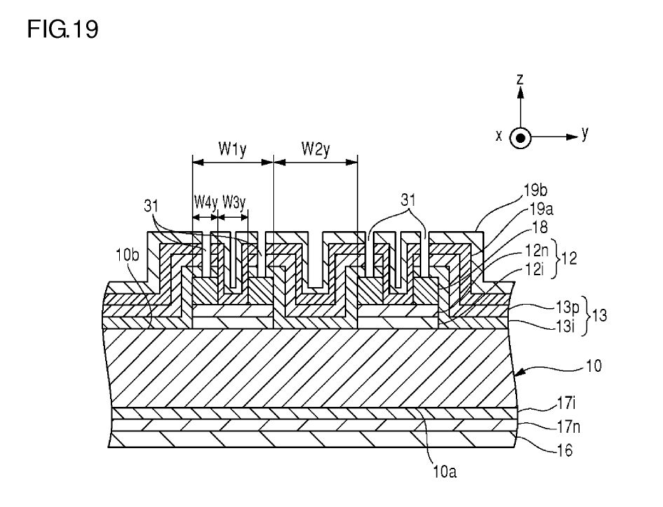

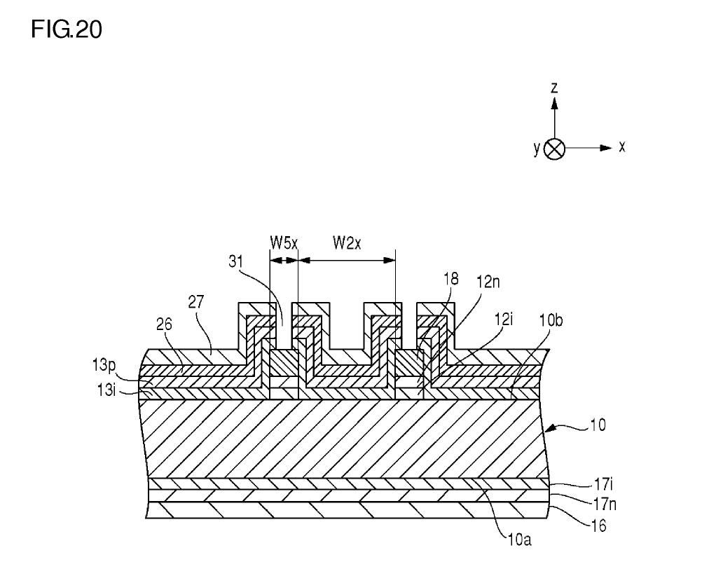

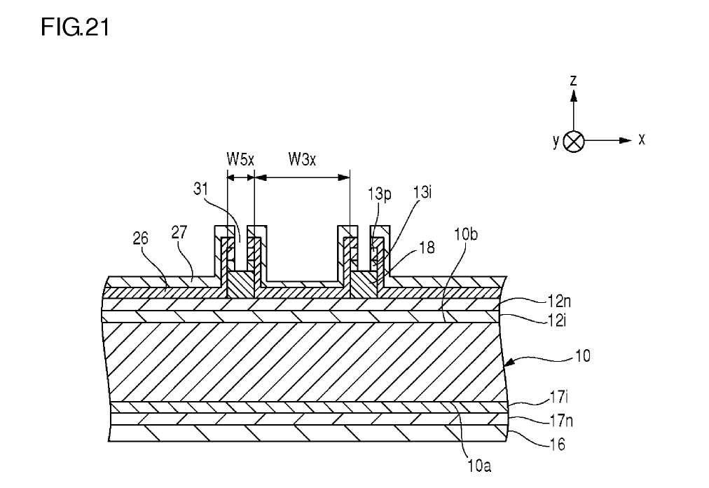

Then, as shown in FIG. 19, FIG. 20 and FIG. 21, part of the conductive layers 26 and 27, which are positioned above the second insulating layer 18, are segmentalized so as to form the isolation grooves 31. This forms the first conductive layer 19a and the second conductive layer 19b from the conductive layers 26 and 27, and these layers 19a and 19b are divided into the first electrode, the second electrode and the sub-electrode. The conductive layers 26 and 27 can be segmentalized by using the photolithography method, for instance.

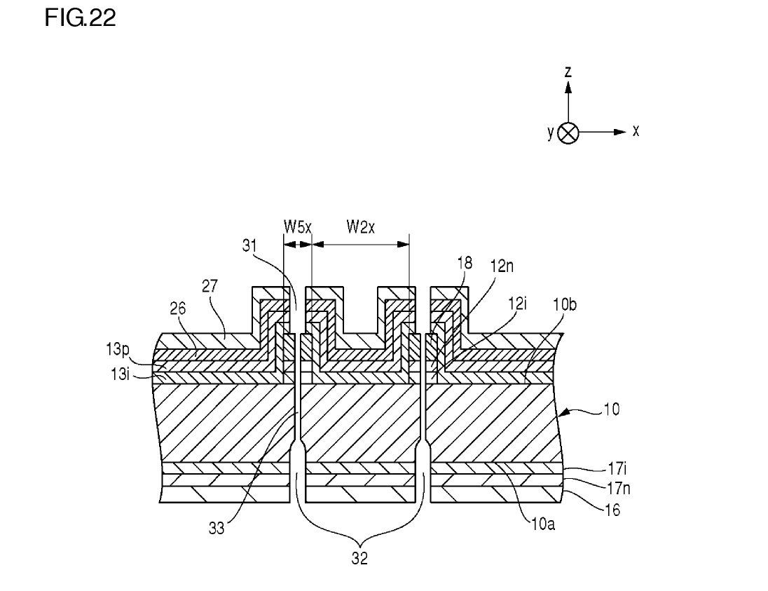

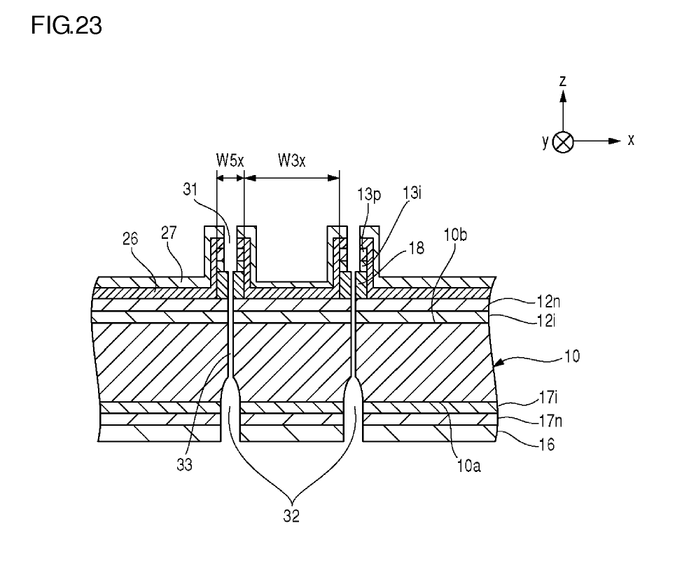

Then, as shown in FIG. 22 and FIG. 23, temporary grooves 32 are formed by laser irradiation applied from the light-receiving surface 70a. After this, the semiconductor substrate 10 is bent along the temporary groove 32; as a result, insulation splits 33 are formed by cutting the semiconductor substrate 10. Thereby, the solar cell 70 is divided into a plurality of sub-cells such that each of the separation regions W5x is held between two adjacent sub-cells.

Through the above-described manufacturing processes, the solar cell 70 shown in FIG. 3, FIG. 4 and FIG. 5 can be formed.

Subsequently, advantageous effects achieved by the solar cell 70 according to the present embodiment will be described below.

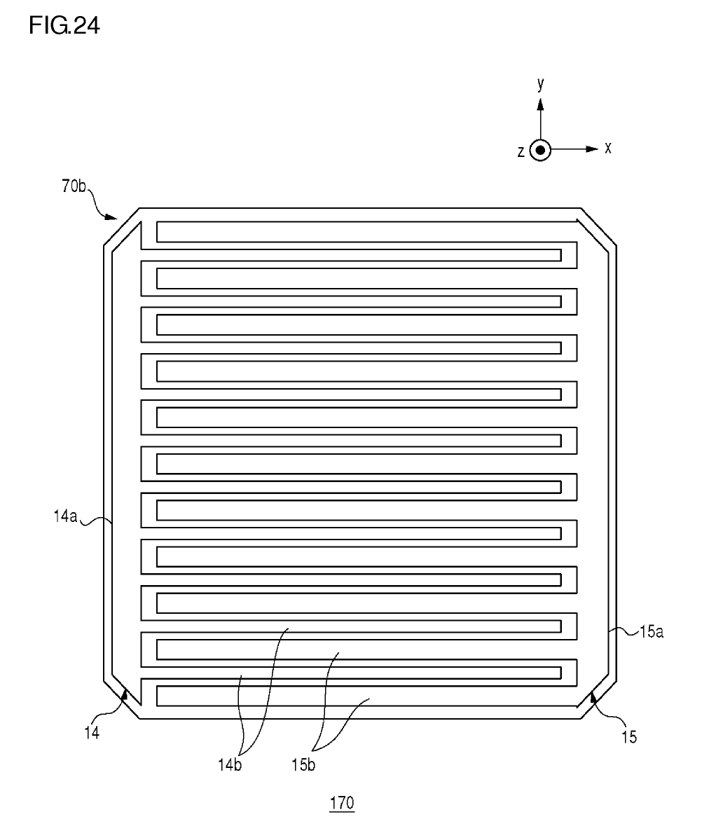

FIG. 24 is a plane view showing a solar cell 170 according to a comparative example. The solar cell 170, which is a back-contact solar cell, has a first electrode 14 and a second electrode 15 provided on a back surface 70b. The first electrode 14 is formed in a comb teeth shape by including a bus-bar electrode 14a, which extends in the y direction, and a plurality of finger electrodes 14b, which extend in the x direction. Similarly, the second electrode 15 is formed in a comb teeth shape by including a bus-bar electrode 15a, which extends in the y direction, and a plurality of finger electrodes 15b, which extend in the x direction. The first electrode 14 and the second electrode 15 are formed such that their different comb teeth interdigitate with each other. Not only the electrodes are formed in comb teeth shapes but also the first conductive region and the second conductive region are formed in comb teeth shapes corresponding to an electrode pattern. Thus, the region where the p-n junction is formed is enlarged and the power generation efficiency is enhanced.

If, on the other hand, the first electrode 14 and the second electrode 15 are formed in comb teeth shapes, the finger electrodes 14b and 15b extend long in the x direction. This may cause the resistance value of the finger electrodes 14b and 15b to increase and lead to a drop in the current collecting efficiency.

In the present embodiment, as shown in FIG. 2, the solar cell 70 is divided into a plurality of sub-cells 71 to 74, so that the length of the finger electrodes 14b and 15b extending in the x direction can be made short. Thereby, the resistance value of the finger electrode 14b and 15b is lowered and therefore the current collecting efficiency can be raised, as compared with the case where the finger electrodes 14b and 15b are each formed in a long shape. As a result, the power generation efficiency of the solar cell 70 can be improved.

In the present embodiment, the sub-electrodes 20, which connect between adjacent sub-cells, are formed together at once in the process of forming the first electrode 14 and the second electrode 15. If a plurality of solar cells, whose length of the finger electrodes extending in the x direction are made short, are to be used, a process of connecting between the solar cells will be additionally required by using the wiring material, after the solar cells have been manufactured. However, in the present embodiment, the process of connecting the sub-cells separately can be skipped. Thus, a solar cell having an increased current collecting efficiency can be manufactured while an increase in the manufacturing cost is being suppressed.

Also, in the present embodiment, the splits, which segmentalize the photoelectric conversion unit, are formed in the boundaries between the sub-cells. This split functions as an insulating portion that makes high the electric resistance, between the photoelectric conversion unit of one of the adjacent sub-cells and the photoelectric conversion unit of the other thereof, or insulates between those photoelectric conversion units. Provision of such grooves electrically isolate the first conductive-type region provided in one of the adjacent sub-cells and the second conductive-type region provided in the other thereof and thereby enhances the efficiency of collecting the carriers generated. As a result, the power generation efficiency of the solar cell 70 can be increased.

Also, in the present embodiment, the sub-electrode 20 connecting between the adjacent sub-cells is of a branched structure, and the sub-electrode 20 is so formed in zigzags as to lie across the separation region W5x. Thus, even though the solar cell 70 is divided into a plurality of sub-cells and, as a result, a force is acting on the x direction, the force applied to the sub-electrode 20 connecting between the sub-cells can be dispersed in oblique directions. Thus, the sub-electrode 20 is less likely to be disconnected or cut even though employed is the fabrication method for providing the insulation split 33 after the electrode layer has been formed together at once. Hence, a drop in the yield attained when the solar cells 70 are fabricated can be suppressed by employing the sub-electrodes 20 having the branched structure.

Also, in the present embodiment, among a plurality of first conductive-type regions or a plurality of second conductive-type regions arranged alternately in the y direction within each sub-cell, regions having the same conductivity type are connected in parallel with each other. This arrangement allows the electrode area of the connectors 20c provided on the separation region W5x to increase and allows the resistance of the sub-electrodes 20 to be reduced. In other words, the electrode area thereof can increase and the resistance thereof can be reduced over the case where the first conductive-type region and the second conductive-type region are connected in a one-to-one correspondence in between the adjacent sub-cells. As a result, the current collecting efficiency obtained by using the sub-electrodes 20 can be enhanced and the power generation efficiency of the solar cell 70 can be improved.

Also, in the present embodiment, the area of one of the extraction sub-cells is made larger than the others thereof. That is, the area of the first sub-cell 71, where provided is the first electrode 14 for extracting the electric power from the first conductive-type region having the same conductivity type as that of the semiconductor substrate 10, is made larger. This structure and arrangement can suppress the adverse effect where the carrier extraction efficiency at the first electrode 14 is lower than that at the second electrode 15.

In the back-contact solar cell, the electrons and holes, which have been generated when the semiconductor substrate 10 absorbs the light, move toward the first electrode 14 and the second electrode 15, respectively. Where the conductivity type of the semiconductor substrate 10 is the n type, the electrons are major carriers while the holes are minority carriers. The holes generated in the region, where the first electrode 14 is provided, move toward the second electrode 15; the electrons generated in the region, where the second electrode 15 is provided, move toward the first electrode 14. Since, at this time, the holes are minority carriers, the amount of holes capable of reaching the second electrode 15 from the region where the bus-bar electrode 14a is provided is smaller than that of electrons capable of reaching the first electrode 14 from the region where the bus-bar electrode 15a is provided. Accordingly, the efficiency of extracting the holes, which are minority carriers, drops in the first sub-cell 71 where the bus-bar electrode 14a is provided.

If, in this case, the area of the first sub-cell 71 is set equal to that of the fourth sub-cell 74, the number of carriers extracted from the first sub-cell 71 having the bus-bar electrode 14a whose current collecting efficiency of minority carriers is low will be smaller than the number of carriers extracted from the fourth sub-cell 74. This makes the number of carriers extracted by the first sub-cell 71 and that by the fourth sub-cell 74 asymmetrical to each other and causes a loss due to the mismatched amounts of current that can be outputted from the respective sub-cells. At the same time, in the present embodiment, the area S1 of the first sub-cell 71 where the carrier extraction efficiency is low is made larger, so that the difference between the number of carriers extracted from the first sub-cell 71 and that from the fourth sub-cell 74 can be small. Thereby, difference in the amounts of current that can be outputted respectively from the sub-cells is small, so that the output characteristics of the solar cells as a whole can be improved.

The summary of one embodiment is as follows. A solar cell 70 according to one embodiment includes:

a photoelectric conversion unit including:
a semiconductor substrate 10 having one conductivity type;
a first conductive-type layer 12n provided on a main surface (a second main surface 10b) of the semiconductor substrate 10, the first conductive-type layer 12n having the same conductivity type as that of the semiconductor substrate 10; and
a second conductive-type layer 13p provided on the main surface (the second main surface 10b), the second conductive-type layer 13p having a conductivity type different from that of the semiconductor substrate 10,
wherein the first conductive-type layer 12n and the second conductive-type layer 13p are arranged alternately in a first direction (y direction) on the main surface (the second main surface 10b), and

an electrode layer 19 provided on the first conductive-type layer 12n and the second conductive-type layer 13p,

wherein the photoelectric conversion unit has a plurality of sub-cells 71 to 74, arranged in a second direction (x direction) that intersects with the first direction (the y direction), and a separation region W5x provided on a boundary between adjacent sub-cells,

the electrode layer 19 having:
a first electrode 14 provided on the first conductive-type layer 12n included in a sub-cell 71 at one end of the plurality of sub-cells;
a second electrode 15 provided on the second conductive-type layer 13p included in a sub-cell 74 at the other end of the plurality of sub-cells; and
a sub-electrode 20 provided across two adjacent sub-cells, the sub-electrode 20 connecting the first conductive-type layer 12n included in one of the two adjacent sub-cells and the second conductive-type layer 13p included in the other thereof,

wherein a sub-cell 71, where the first electrode 14 is provided, has a larger area of the main surface (the second main surface 10b) than that of a sub-cell 74 where the second electrode 15 is provided.

As one of the plurality of sub-cells, the photoelectric conversion unit has intermediate sub-cells 72 and 73 located between the sub-cell 71, where the first electrode 14 is provided, and the sub-cell 74, where the second electrode 15 is provided, and

the sub-cell 71, where the first electrode 14 is provided, may have a larger area of the main surface (the second main surface 10b) than that of each of the intermediate sub-cells 72 and 73.

The sub-electrode 20 includes:

a first sub-electrode portion 20n provided on the first conductive-type layer 12n included in one of the two adjacent sub-cells;

a second sub-electrode portion 20p provided on the second conductive-type layer 13p included in the other thereof; and

a connector 20c provided between the first sub-electrode portion 20n and the second sub-electrode portion 20p,

wherein the connector 20c may extend, in the separation region W5x, in directions A and B that intersect with the first direction (the y direction) and the second direction (the x direction).

A split, which passes through at least the semiconductor substrate 10, may be formed in the separation region W5x.

The semiconductor substrate 10 and the first conductive-type layer 12n each may contain an n-type impurity, and

the second conductive-type layer 13p may contain a p-type impurity.

### Second Embodiment

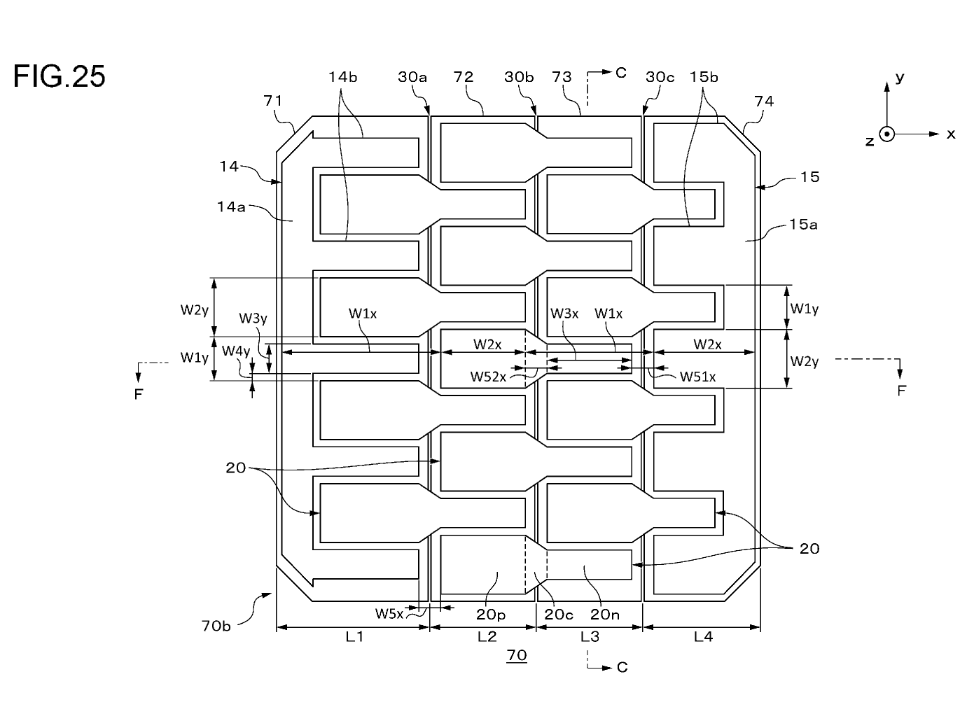

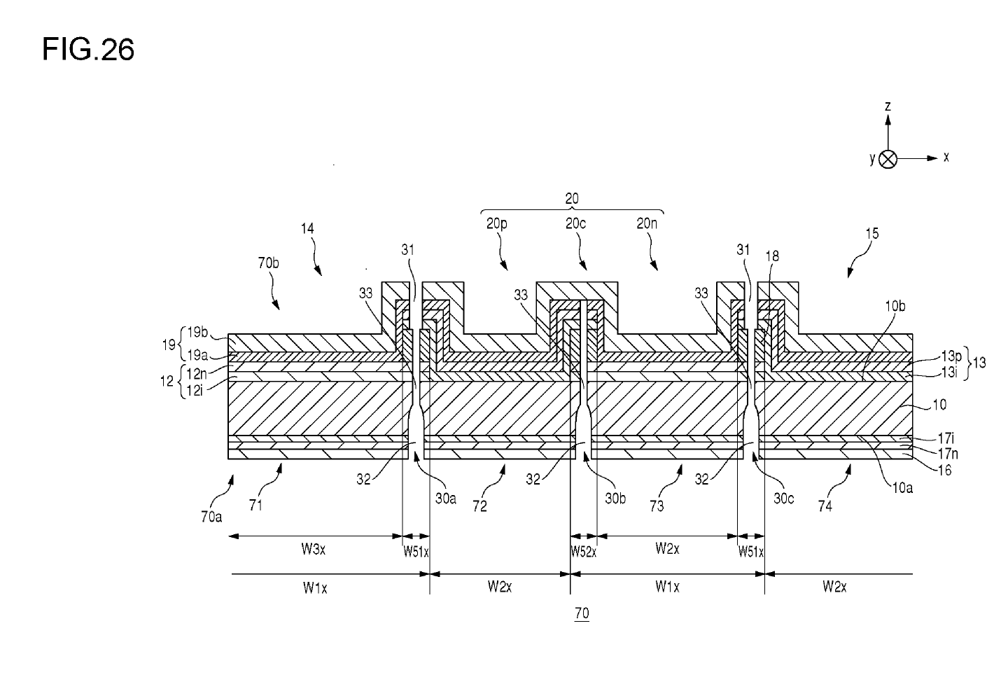

A detailed description is now given of a structure of a solar cell 70 according to a second embodiment, by reference to FIG. 25 and FIG. 26. In the first embodiment, the connectors 20c of the sub-electrode 20 extend in the directions A and B tilted relative to the x direction. The second embodiment differs from the first embodiment in the feature where the connectors 20c extend in the x direction. A description is given hereunder centering around differences from the first embodiment.

FIG. 25 is a plane view of the solar cell 70 according to the second embodiment and is an illustration showing a back surface 70b of the solar cell 70. The structure of a light-receiving surface 70a of the solar cell 70 according to the second embodiment is similar to that of FIG. 1.

As shown in FIG. 25, each sub-electrode 20 has a first sub-electrode portion 20n, a second sub-electrode portion 20p, and a connector 20c. The sub-electrode 20 is provided across between adjacent sub-cells, and connects the first conductive-type region in one of the adjacent sub-cells and the second conductive-type region in the other thereof. A separation region W5x is provided between adjacent sub-cells, and the boundaries 30a to 30c between the sub-cells are located in the separation regions W5x. As the separation regions there are provided a first separation region W51x, where no connector 20c is provided, and a second separation region W52x, where the connector 20c is provided.

FIG. 26 is a cross-sectional view, taken along the line F-F of FIG. 25, showing a structure of the solar cell 70 according to the second embodiment. The structure of a cross section taken along the line C-C of FIG. 25 is similar to that of FIG. 3.

First layered products 12 and second layered products 13, which are formed on the second main surface 10b of the semiconductor substrate 10, are arranged alternately in the x direction such that the second insulating layer 18 located in each of the separation regions W51x and W52x is held between the first layered product 12 and the second layered product 13. FIG. 26 shows a cross section of the solar cell 70 where a third region W3x, which is the first conductive-type region, is provided in the positions of the first sub-cell 71 and the third sub-cell 73, and a second region W2x, which is the second conductive-type region, is provided in the positions of the second sub-cell 72 and the fourth sub-cell 74. Thus, the first conductive-type region and the second conductive-type region are provided opposite to each other, in the x direction, with the separation regions W51x and W52x being held therebetween.

Boundaries 30a to 30c are provided in the separation regions W51x and W52x where the second insulating layers 18 are formed. An isolation groove 31, which isolates between the first electrode 14 and the sub-electrode 20, or an isolation groove 31, which isolates between the second electrode 15 and the sub-electrode 20, is provided in the boundaries 30a and 30c provided in the first separation region W51x. On the other hand, no isolation groove is provided in the boundary 30b where the second separation region W52x is provided. Thus, the electrode layer 19 remaining in the second separation region W52x becomes the connector 20c that connects between adjacent sub-cells.

As shown in FIG. 25, the area of one of the extraction sub-cells is made larger than the others thereof in this second embodiment as well. That is, the area of the first sub-cell 71, where provided is the first electrode 14 for extracting the electric power from the first conductive-type region having the same conductivity type as that of the semiconductor substrate 10, is made larger. This structure and arrangement can suppress the adverse effect where the carrier extraction efficiency at the first electrode 14 is lower than that at the second electrode 15.

The present invention has been described by referring to each of the above-described embodiments. However, the present invention is not limited to the above-described embodiments only, and those resulting from any combination of them or substitution as appropriate are also within the scope of the present invention.

(First Modification)

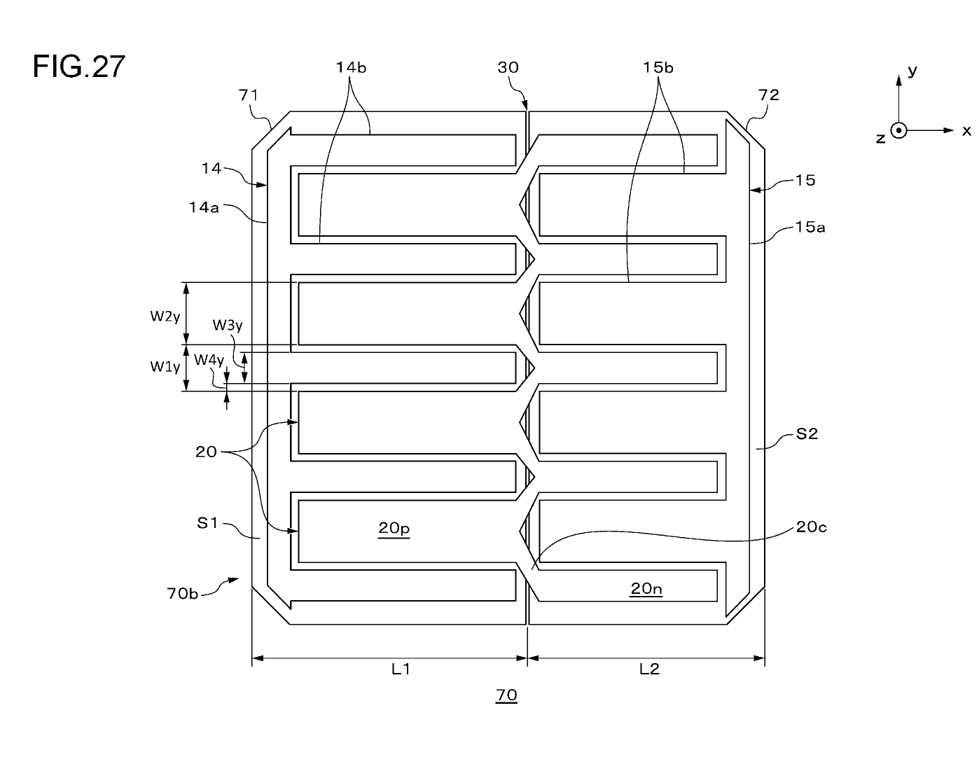

FIG. 27 is a plane view showing a solar cell 70 according to a first modification. In the above-described embodiments, the solar cell 70 is divided into four sub-cells 71 to 74. In the first modification, the solar cell 70 is divided into two sub-cells 71 and 72.

The first electrode 14 is provided in the first sub-cell 71, and the second electrode 15 is provided in the second sub-cell 72. A boundary 30, which demarcates the first sub-cell 71 and the second sub-cell 72, is formed therebetween. A sub-electrode 20, which connects between the first sub-cell 71 and the second sub-cell 72, is so arranged as to lie across the boundary 30 between the first sub-cell 71 and the second sub-cell 72. Each sub-electrode 20 has a first sub-electrode portion 20n, a second sub-electrode portion 20p, and a connector 20c.

In this first modification, too, the solar cell 70 is divided into the sub-cells such that an area Sn of the first sub-cell 71, where the first electrode 14 is provided, is larger than an area Sp of the second sub-cell 72, where the second electrode 15 is provided. In other words, length L1 of the first sub-cell in the x direction is set larger than length L2 of the second sub-cell in the x direction. This structure and arrangement can suppress the adverse effect where the carrier extraction efficiency at the first electrode 14 is lower than that at the second electrode 15.

Note that the number of sub-cells in the solar cell 70 is not limited to this, and the solar cell 70 may be divided into three sub-cells or five or more sub-cells. Though FIG. 27 shows a case corresponding to the first embodiment, the solar cell 70 may be arranged such that the sub-electrodes extend in the x direction as in the second embodiment, and such a solar cell 70 as this may be divided into three sub-cells or five or more sub-cells. In this case, the area Sn of an extraction sub-cell having the first electrode 14 is preferably larger than the area Sp of an extraction sub-cell having the second electrode 15. Also, an area Sc of intermediate sub-cell(s) positioned between the extraction sub-cells at both ends is preferably larger than the area Sp of the extraction sub-cell having the second electrode 15.

(Second Modification)

In the above-described embodiments and the first modification, the description has been given of the case where the conductivity type of the semiconductor substrate 10 is the n type, the first conductive-type is the n type, and the second conductive type is the p type. In a second modification, the conductivity type of the semiconductor substrate 10 is the p type, the first conductive-type is the p type, and the second conductive type is the n type. In this case, too, the area of the extraction sub-cell having the first electrode 14, which is connected to the first conductive-type region having the same conductivity type as that of the semiconductor substrate 10, may be relatively larger. Thereby, the same advantageous effects as those achieved by the above-described embodiments can be achieved.

(Third Modification)

In the above-described embodiments, splits are provided in the respective boundaries 30a to 30c. A third modification may be configured such that no splits running through the photoelectric conversion unit is formed in the boundaries 30a to 30c. Also, after the splits have been formed, a filler having a function of bonding the adjacent sub-cells may be provided in the splits. The filler is preferably made of a material capable of insulating between any adjacent sub-cells; a resin material such as ethylene-vinyl acetate copolymer (EVA), polyvinyl butyral (PVB) or polyimide may be used as the filler. If the structure is employed where no splits is formed or the filler is provided, the strength of the boundaries 30a to 30b by which any adjacent sub-cells are demarcated therebetween can be enhanced and the solar cell 70 can be so structured as to have higher strength as a whole.

It should be understood that the invention is not limited to the above-described embodiments and modifications, but may be further modified into various forms on the basis of the spirit of the invention. Additionally, those modifications are included in the scope of the invention.

What is claimed is:

1. A solar cell comprising:
a photoelectric conversion unit including:
a semiconductor substrate having one conductivity type;
a first conductive-type layer provided on a main surface of the semiconductor substrate, the first conductive-type layer having the same conductivity type as that of the semiconductor substrate; and
a second conductive-type layer provided on the main surface, the second conductive-type layer having a conductivity type different from that of the semiconductor substrate,
wherein the first conductive-type layer and the second conductive-type layer are arranged alternately in a first direction on the main surface, and
an electrode layer provided on the first conductive-type layer and the second conductive-type layer,
wherein the photoelectric conversion unit has a plurality of sub-cells, arranged in a second direction that intersects with the first direction, and a separation region provided on a boundary between adjacent sub-cells,
the electrode layer having:
a first electrode provided on the first conductive-type layer included in a sub-cell at one end of the plurality of sub-cells;
a second electrode provided on the second conductive-type layer included in a sub-cell at the other end of the plurality of sub-cells; and
a sub-electrode provided across two adjacent sub-cells, the sub-electrode connecting the first conductive-type layer included in one of the two adjacent sub-cells and the second conductive-type layer included in the other thereof,
wherein a sub-cell, where the first electrode is provided, has a larger area of the main surface than that of a sub-cell where the second electrode is provided.

2. The solar cell according to claim 1, wherein, as one of the plurality of sub-cells, the photoelectric conversion unit has an intermediate sub-cell located between a sub-cell, where the first electrode is provided, and a sub-cell, where the second electrode is provided, and
wherein the sub-cell, where the first electrode is provided, has a larger area of the main surface than that of the intermediate sub-cell.

3. The solar cell according to claim 1, the sub-electrode including:
a first sub-electrode portion provided on the first conductive-type layer included in one of the two adjacent sub-cells;
a second sub-electrode portion provided on the second conductive-type layer included in the other thereof; and
a connector provided between the first sub-electrode portion and the second sub-electrode portion,
wherein the connector extends, in the separation region, in directions that intersect with the first direction and the second direction.

4. The solar cell according to claim 1, wherein a split, which passes through at least the semiconductor substrate, is formed in the separation region.

5. The solar cell according to claim 1, wherein the semiconductor substrate and the first conductive-type layer each contains an n-type impurity, and
wherein the second conductive-type layer contains a p-type impurity.
